(19) United States
(12) Patent Application Publication
(10) Pub. No.: US 2025/0298089 A1
(43) Pub. Date: Sep. 25, 2025

(54) ELECTRIC LEAKAGE DETECTION CIRCUIT

(71) Applicant: Panasonic Automotive Systems Co., Ltd., Kanagawa (JP)

(72) Inventor: Naofumi OTA, Shizuoka (JP)

(21) Appl. No.: 19/043,026

(22) Filed: Jan. 31, 2025

(30) Foreign Application Priority Data
Mar. 22, 2024 (JP) 2024-045832

(51) Int. Cl. G01R 31/52; G01R 31/58; H02H 3/16

(52) U.S. Cl. CPC G01R 31/52; G01R 31/58; H02H 3/165

(57) ABSTRACT

An electric leakage detection circuit includes a ground fault detection circuit and a self-diagnosis circuit. The detection circuit connected to power supply lines to detect a ground fault current to a ground potential of each power supply line. The self-diagnosis circuit generates a short-circuit path by which the power supply lines are selectively short-circuited to a connection line of the ground potential. A first limiting resistor of the self-diagnosis circuit includes resistance elements electrically connected in series. One end of the first limiting resistor is connected to the connection line of the ground potential. A relay circuit of the self-diagnosis circuit is provided between the power supply lines and a side opposite to the connection line of the ground potential. The relay circuit switches, among the power supply lines, a power supply line to be electrically connected to the first limiting resistor and given the short-circuit path.

### CROSS-REFERENCE TO RELATED APPLICATIONS

This application is based upon and claims the benefit of priority from Japanese Patent Application No. 2024-045832, filed on Mar. 22, 2024, the entire contents of which are incorporated herein by reference.

### FIELD

The present disclosure relates generally to an electric leakage detection circuit.

### BACKGROUND

In recent years, in a power conversion device such as a charger provided in an electric vehicle, an insulation monitoring circuit (electric leakage detection circuit) for detecting an electric leakage current is installed for the purpose of avoiding an electric shock on a human body in consideration for a current direction being bidirectional to cope with both charging and discharging.

For example, JP 2015-001423 A discloses a technique related to an insulation state detection device that detects a ground fault and an insulation state with respect to a ground potential based on a state of charge of a flying capacitor.

In such an insulation monitoring circuit, the failure involves a serious risk. Therefore, an independent self-diagnosis circuit for confirming the feasibility of the insulation monitoring circuit itself is provided.

Under such circumstances, an in-vehicle charger is required to be downsized from the viewpoint of installability. However, it is required to have sufficient resistance to a high voltage such as a lightning surge. Therefore, there is a problem that a circuit scale (physique) of a self-diagnosis circuit increases.

In addition, for example, in an in-vehicle charger that can be operated by inputting an AC voltage from each of a three-phase AC power supply and a single-phase AC power supply, there is a problem that the circuit scale of the self-diagnosis circuit further increases.

### SUMMARY

An electric leakage detection circuit according to one aspect of the present disclosure includes a ground fault detection circuit and a self-diagnosis circuit. The ground fault detection circuit is electrically connected to power supply lines to which AC power is supplied. The ground fault detection circuit is configured to detect a ground fault current with respect to a ground potential of each of the power supply lines. The self-diagnosis circuit is configured to generate a short-circuit path by which each of the power supply lines is selectively short-circuited to a connection line of the ground potential. The self-diagnosis circuit includes a first limiting resistor and a relay circuit. The first limiting resistor includes a plurality of resistance elements electrically connected in series. One end of the first limiting resistor being electrically connected to the connection line of the ground potential. The relay circuit is provided between the power supply lines and a side opposite to the connection line of the ground potential of the first limiting resistor. The relay circuit is configured to switch, among the power supply lines, a power supply line to be electrically connected to the first limiting resistor and given the short-circuit path.

### BRIEF DESCRIPTION OF THE DRAWINGS

FIG. 1 is a diagram illustrating an example of a configuration of a charging system according to an embodiment; and

FIG. 2 is a diagram illustrating an example of a configuration of an insulation monitoring circuit (electric leakage detection circuit) of FIG. 1.

### DETAILED DESCRIPTION

Hereinafter, embodiments of a self-diagnosis circuit, an electric leakage detection circuit (insulation monitoring circuit), a power conversion device (in-vehicle charger), a vehicle, and a charging system according to the present disclosure will be described with reference to the drawings.

In the description of the present disclosure, components having the same or substantially the same functions as those described above with respect to the previously described drawings are denoted by the same reference numerals, and the description thereof may be appropriately omitted. In addition, even in the case of representing the same or substantially the same portion, the dimensions and ratios may be represented differently from each other depending on the drawings. Additionally, from the viewpoint of ensuring visibility of the drawings, in the description of each drawing, only main components are denoted by reference numerals, and even components having the same or substantially the same functions as those described before in the previous drawings may not be denoted by reference numerals.

In the description of the present disclosure, components having the same or substantially the same function may be distinguished and described by adding alphanumeric characters to the end of reference numerals. Alternatively, in a case where plural components having the same or substantially the same functions are not distinguished, the components may be integrated and described by omitting alphanumeric characters added to the end of the reference numerals.

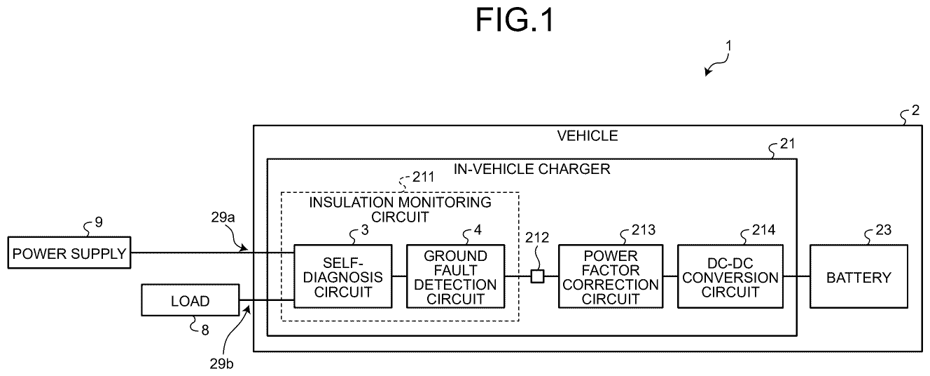

FIG. 1 is a diagram illustrating an example of a configuration of a charging system 1 according to an embodiment. As illustrated in FIG. 1, the charging system 1 includes a vehicle 2, a load 8, and a power supply 9. In addition, the vehicle 2 includes an in-vehicle charger 21 and a battery 23.

The vehicle 2 is one of various moving bodies configured to be drivable using electric power from the battery 23, such as a passenger car, a cargo vehicle, a passenger vehicle, a motorcycle, and an electric kickboard.

Note that the technology according to the embodiment is not limited to the vehicle 2, and may be applied to various power conversion devices provided in, for example, an aircraft, a game facility, an uninterruptible power supply device, and the like.

The vehicle 2 may be configured to be able to operate vehicle equipment (electric component) using, for example, electric power from the battery 23. Examples of the vehicle equipment may include a navigation device, an audio device, an air conditioner, a power window, a defogger, an electronic control unit (ECU), a global positioning system (GPS) module, a vehicle camera, and the like.

The in-vehicle charger 21 is a power conversion device provided in the vehicle 2. In the present embodiment, the in-vehicle charger 21 that is configured to be operable with either single-phase AC power or three-phase AC power will be exemplified. The in-vehicle charger 21 converts single-phase or three-phase AC power supplied from the power supply 9 into DC power, and supplies the DC power to the battery 23. The in-vehicle charger 21 converts DC power from the battery 23 into AC power, and supplies single-phase or three-phase AC power to the load 8 connected to an AC socket 29a or an in-vehicle socket 29b of the vehicle 2.

Note that the in-vehicle charger 21 may not be compatible with both the single phase and the three phases, and may be configured to be operable in either one of these phases. Additionally, the in-vehicle charger 21 is not limited to the single-phase and three-phase (plural phases), and may be configured to be operable by two-phase (plural phases) AC power.

The battery 23 stores electric power supplied from the power supply 9 via the in-vehicle charger 21. The battery 23 only needs to be able to store electric power for supplying power to a traveling motor (main electric motor) or an electric component provided in the vehicle 2, or the load 8 connected to the AC socket 29a or the in-vehicle socket 29b of the vehicle 2. A battery such as a lithium-ion battery, a nickel hydrogen battery, or an all-solid-state battery can be appropriately used as the battery 23.

The load 8 is detachably connected to the AC socket 29a and the in-vehicle socket 29b of the vehicle 2. The load 8 may be an electronic device that receives power supply from the vehicle 2, such as a home appliance or a smartphone. The load 8 may be an external power storage device or a power facility that receives power supply from the vehicle 2, for example, a home storage battery or a power purchase device of a charging station.

The AC socket 29a of the vehicle 2 refers to a power source socket for charging and discharging the vehicle 2. The AC socket 29a can be provided at a position available from the outside of the vehicle 2. The AC socket 29a is connected to the power source 9 when the vehicle 2 is charged. The AC socket 29a is connected to the load 8 at the time of discharge from the vehicle 2. In one example, the AC socket 29a of the vehicle 2 is compliant to both the single-phase AC power and the three-phase AC power. However, the AC socket 29a may be compliant to either one of the single-phase AC power and the three-phase AC power.

The in-vehicle socket 29b of the vehicle 2 refers to a power source socket for discharging the vehicle 2. The in-vehicle socket 29b is provided in, for example, a vehicle interior (inside the vehicle) of the vehicle 2. The in-vehicle socket 29b is connected to the load 8 at the time of discharge from the vehicle 2. In one example, the in-vehicle socket 29b of the vehicle 2 is compliant to the single-phase AC power, but may be compliant to both the single-phase AC power and the three-phase AC power.

The power supply 9 is an AC power supply such as a power supply provided in a quick charging facility or a commercial power supply. Note that the power supply 9 is not limited to a single-phase AC power supply and a three-phase AC power supply (multi-phase AC power supply), and a two-phase AC power supply (multi-phase AC power supply) may be used. In the present embodiment, as the power supply 9 that supplies AC power to the in-vehicle charger 21 (power conversion device) of the vehicle 2, a case where an AC power supply of a single-phase or three-phases can be used will be exemplified.

As illustrated in FIG. 1, the in-vehicle charger 21 includes an insulation monitoring circuit 211, a power factor correction (PFC) circuit 213, and a DC-DC conversion circuit 214. Note that the in-vehicle charger 21 according to the present disclosure is not limited to the configuration of FIG. 1, and may have other configurations. For example, the power factor correction circuit 213 is not treated as an essential component in the in-vehicle charger 21, and instead, another rectifying and smoothing circuit may be used.

The insulation monitoring circuit 211 is an electric leakage detection circuit provided in the in-vehicle charger 21. The insulation monitoring circuit 211 is electrically connected to the power factor correction circuit 213. When the load 8 or the power supply 9 is connected to the in-vehicle charger 21, the insulation monitoring circuit 211 is electrically connected to the load 8 or the power supply 9. The insulation monitoring circuit 211 operates at the time of discharging to the load 8 connected to the in-vehicle charger 21 and detects a leakage current.

The power factor correction circuit 213 is electrically connected to the insulation monitoring circuit 211 and the DC-DC conversion circuit 214. The power factor correction circuit 213 generates a DC voltage by rectifying and smoothing the AC voltage from the power supply 9.

The DC-DC conversion circuit 214 is electrically connected to the power factor correction circuit 213 and the battery 23. The DC-DC conversion circuit 214 converts the DC voltage generated by the power factor correction circuit 213 into an AC voltage again, and then performs rectification and smoothing to generate a DC voltage of an optional preset voltage. In addition, the DC-DC conversion circuit 214 converts the DC voltage from the battery 23 into an AC voltage, and then performs rectification and smoothing to generate a DC voltage of an optional preset voltage.

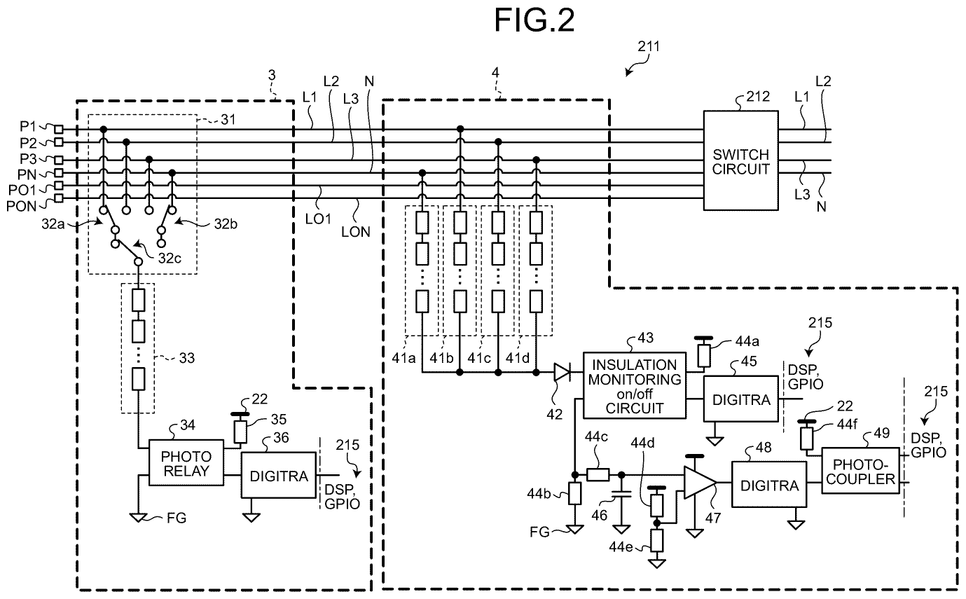

Note that the in-vehicle charger 21 may further include a noise removal filter (not illustrated) that serves to suppress entry of noise from the power supply 9 and outflow of noise to the power supply 9. In one example, this noise removal filter can be provided between a switch circuit 212 (see FIG. 2) and the power factor correction circuit 213, but may be provided at another place.

The insulation monitoring circuit 211 according to the present disclosure will be described in detail with reference to the drawings.

FIG. 2 is a diagram illustrating an example of a configuration of the insulation monitoring circuit 211 of FIG. 1. As illustrated in FIGS. 1 and 2, the insulation monitoring circuit 211 includes a self-diagnosis circuit 3 and a ground fault detection circuit 4.

The self-diagnosis circuit 3 is electrically connected between charging/discharging terminals P1 to P3 and PN of the in-vehicle charger 21 and the ground fault detection circuit 4 via the power supply lines L1 to L3 and N.

The charging/discharging terminals P1 to P3 and PN of the in-vehicle charger 21 are terminals electrically connected to the AC socket 29a (power source socket for charging/discharging) of the vehicle 2. The power supply lines L1 to L3 and N are connected to the charging/discharging terminals P1 to P3 and PN, respectively. Thus, when the vehicle 2 is charged, AC power from the external power supply 9 is supplied to the power supply lines L1 to L3 and N. When the vehicle 2 is discharged, AC power based on DC power from the battery 23 is supplied to the power supply lines L1 to L3 and N.

In one example, the power supply line L1 is a voltage line through which a single-phase current from a single-phase AC power supply or a U-phase (first phase) current from a three-phase AC power supply flows. In one example, the power supply line L2 is a voltage line that is not electrically connected to a single-phase AC power supply and through which a V-phase (second phase) current from a three-phase AC power supply flows. In one example, the power supply line L3 is a voltage line that is not electrically connected to a single-phase AC power supply and through which a W-phase (third phase) current from a three-phase AC power supply flows. In one example, the power supply line N is a neutral line electrically connected to each of a single-phase or three-phase AC power supply and a ground potential.

The self-diagnosis circuit 3 is electrically connected between the power supply lines L1 to L3 and N and a ground line FG functionally grounded, such as a metal chassis of the vehicle 2.

The self-diagnosis circuit 3 is a circuit for confirming the feasibility of the ground fault detection circuit 4, namely, a circuit that performs self-diagnosis in the insulation monitoring circuit 211. Specifically, the self-diagnosis circuit 3 generates a short circuit to the ground line FG that is functionally grounded for a phase to be subjected to ground fault detection by the ground fault detection circuit 4. In other words, the self-diagnosis circuit 3 generates a short-circuit path by which each of the L1 to L3 phases and the N phases, namely, each of the power supply lines L1 to L3 and N is selectively short-circuited to the connection line FG of the functionally grounded potential.

As illustrated in FIG. 2, the self-diagnosis circuit 3 includes a relay circuit 31, a limiting resistor 33, a photo relay 34, and a digital transistor (hereinafter, simply referred to as “digitra”) 36. In place of the digitra 36, another circuit element may be used. In one example, a bipolar transistor and one or more resistor may be used in place of the digitra 36.

The relay circuit 31 is electrically connected between each of the power supply lines L1 to L3 and N and the limiting resistor 33. In the example of FIG. 2, the relay circuit 31 includes three C contact relays 32a to 32c that electrically connect the limiting resistor 33 to one of the four power supply lines L1 to L3 and N.

In the example of FIG. 2, one end of the C contact relay 32a is selectively and electrically connected to one of the power supply lines L1 and L2, and the other end is electrically connected to the limiting resistor 33 via the C contact relay 32c. One end of the C contact relay 32b is selectively and electrically connected to one of the power supply lines L3 and N, and the other end is electrically connected to the limiting resistor 33 via the C contact relay 32c.

Thus, in the example of FIG. 2, the transfer contact (common contact) of the C contact relay 32c is electrically connected to the limiting resistor 33. One of a make contact (normally open (NO) contact) and a break contact (normally closed (NC) contact) of the C contact relay 32c is electrically connected to the transfer contact of the C contact relay 32a, and the other is electrically connected to the transfer contact of the C contact relay 32b. One of the make contact and the break contact of the C contact relay 32a is electrically connected to the power supply line L1, and the other is electrically connected to the power supply line L2. One of the make contact and the break contact of the C contact relay 32b is electrically connected to the power supply line L3, and the other is electrically connected to the power supply line N.

Note that the combination illustrated in FIG. 2 as to the C contact relays 32a and 32b and the power supply lines to which they are selectively connected is one example, and another combination such as providing the C contact relay 32a between the power supply lines L1 and L3 can be used.

The number of the C contact relays 32 provided in the relay circuit 31 is appropriately changed according to the number of lines of the target power supply line. In one example, in the case of a single-phase two-wire type including one voltage line and one neutral line, the relay circuit 31 includes one C contact relay 32 that electrically connects the limiting resistor 33 to either one of the two power supply lines.

The relay circuit 31 operates each of the C contact relays 32a to 32c under the control of a control circuit 215 (for example, DSP) of the in-vehicle charger 21. As a result, the relay circuit 31 switches the phase to which the limiting resistor 33 is connected, among the phases corresponding to the power supply lines L1 to L3 and N. The phase to which the limiting resistor 33 is connected refers to a phase to be subjected to self-diagnosis for confirming the feasibility of the ground fault detection circuit 4 among the phases. Thus, the relay circuit 31 switches a phase to be functionally grounded for self-diagnosis to generate a short circuit among multiple phases to be subjected to ground fault detection by the ground fault detection circuit 4.

The limiting resistor 33 is electrically connected between the relay circuit 31 and the photo relay 34. The resistance value of the limiting resistor 33 is appropriately determined according to a withstand voltage requirement required for the self-diagnosis circuit 3 such as a lightning surge. The limiting resistor 33 includes a plurality of high withstand voltage resistance elements (resistance elements) electrically connected in series. The limiting resistor 33 according to the embodiment is an example of a first limiting resistor.

One end of the photo relay 34 on the light emitting element side is electrically connected to an insulated power supply 22 of the vehicle 2 via a resistor 35. The other end on the light emitting element side of the photo relay 34 is electrically connected to the output end of the digitra 36. One end of the photo relay 34 on the light receiving element side is electrically connected to one of the power supply lines L1 to L3 and N via the relay circuit 31 and the limiting resistor 33. The other end of the photo relay 34 on the light receiving element side is electrically connected to the ground line FG that is functionally grounded.

The digitra 36 is electrically connected between one end of the light emitting element side of the photo relay 34 on the side opposite to the insulated power supply 22 of the vehicle 2 and a ground line FG functionally grounded. A control end of the digitra 36 is electrically connected to a signal line (for example, GPIO) to which a control signal is supplied from the control circuit 215 of the in-vehicle charger 21.

The digitra 36 operates the photo relay 34 under control of the control circuit 215 of the in-vehicle charger 21. In one example, the digitra 36 turns on the photo relay 34 every time the relay circuit 31 changes a power supply line to which the limiting resistor 33 is connected. The digitra 36 includes a bipolar transistor (not illustrated) whose base is electrically connected to a GPIO line via an input resistor (not illustrated) and whose emitter is electrically connected to a ground line FG whose function is grounded via a base-emitter resistor (not illustrated). In the digitra 36, the input resistor generates current in accordance with the voltage level of the GPIO line, and generates a collector current in accordance with the magnitude of the generated current. The cathode of the photo relay 34 is electrically connected to the collector of the bipolar transistor of the digitra 36. When a collector current flows through a light emitting element of the photo relay 34, a switch (not illustrated) provided on the light receiving element side is turned on, and thereby the power supply line selectively connected via the relay circuit 31 and the limiting resistor 33 is functionally grounded.

As described above, the self-diagnosis circuit 3 according to the present embodiment selectively causes each of the power supply lines L1 to L3 and N to be functionally grounded in accordance with the control of the control circuit 215 of the in-vehicle charger 21 so as to generate a short circuit. When each of the power supply lines L1 to L3 and N is selectively functionally grounded by the self-diagnosis circuit 3 to generate a short circuit, the potential of the ground line FG functionally grounded drops by a voltage generated by the limiting resistor. As a result, as will be described later, current flows through a detection shunt resistor 44b whose one end is electrically connected to the ground line FG. Thus, the self-diagnosis circuit 3 selectively causes each of the power supply lines L1 to L3 and N to be functionally grounded to generate a short circuit, thereby generating a state in which a Y capacitor (not illustrated) provided at a subsequent stage of the ground fault detection circuit 4 is subjected to dielectric breakdown in order to attenuate common noise in the in-vehicle charger 21, namely, a state of the in-vehicle charger 21 to be detected by the insulation monitoring circuit 211 without causing dielectric breakdown of the Y capacitor.

The ground fault detection circuit 4 is electrically connected between charging/discharging terminals P1 to P3 and PN of the in-vehicle charger 21 and the switch circuit 212 via the power supply lines L1 to L3 and N. The ground fault detection circuit 4 is electrically connected between the power supply lines L1 to L3 and N and the ground line FG functionally grounded.

The ground fault detection circuit is a circuit that detects a ground fault (electric leakage) current with respect to a ground potential of each of the power supply lines L1 to L3 and N. In other words, the ground fault detection circuit 4 is a circuit that detects a ground fault (electric leakage) current generated by dielectric breakdown of a target Y capacitor (not illustrated) provided between each of the power supply lines L1 to L3 and N, and the ground line FG functionally grounded at a subsequent stage of the ground fault detection circuit 4. Specifically, the ground fault detection circuit 4 detects a ground fault current flowing through the detection shunt resistor 44b when the target Y capacitor (not illustrated) undergoes dielectric breakdown, thereby detecting the insulation state around the in-vehicle charger 21. The ground fault detection circuit 4 sets, as a detection range, a series of systems in which a closed circuit is formed by the in-vehicle charger 21, the load 8, the human body, and the like. In addition, the ground fault detection circuit 4 is capable of detecting at all times when discharging from the vehicle 2, and is capable of detecting before electric shock on a human body.

As illustrated in FIG. 2, the ground fault detection circuit 4 includes limiting resistors 41a to 41d, a high withstand voltage diode 42, an insulation monitoring on/off circuit 43, a digitra 45, a digitra 48, a Y capacitor 46, an insulation determination comparator 47, and a photocoupler 49.

Each of the limiting resistors 41a to 41d is electrically connected in parallel between each of the power supply lines L1 to L3 and N, and the high withstand voltage diode 42. Each of the limiting resistors 41a to 41d has the same configuration as the limiting resistor 33 of the self-diagnosis circuit 3. Thus, each of the limiting resistors 41a to 41d includes a plurality of high withstand voltage resistance elements (resistance elements) electrically connected in series. Each of the limiting resistors 41a to 41d according to the embodiment is an example of a second limiting resistor.

The anode of the high withstand voltage diode 42 is electrically connected to the opposite side of each of the limiting resistors 41a to 41d from the power supply lines L1 to L3 and N. The cathode of the high withstand voltage diode 42 is electrically connected to one end (the collector of the bipolar transistor) on the light receiving element side of the insulation monitoring on/off circuit 43, similarly to the limiting resistor 33 of the self-diagnosis circuit 3. Thus, the cathode of the high withstand voltage diode 42 is electrically connected to the connection line FG of the potential functionally grounded via the detection shunt resistor 44b of a ground fault current.

The insulation monitoring on/off circuit 43 includes a photo relay and has the same configuration as the photo relay 34 of the self-diagnosis circuit 3. One end of the insulation monitoring on/off circuit 43 on the light emitting element side is electrically connected to the insulated power supply 22 of the vehicle 2 via a resistor 44a. The other end on the light emitting element side of the insulation monitoring on/off circuit 43 is electrically connected to the output terminal of the digitra 45. One end of the insulation monitoring on/off circuit 43 on the light receiving element side is electrically connected to the power supply lines L1 to L3 and N via the limiting resistors 41a to 41d and the high withstand voltage diode 42. The other end of the insulation monitoring on/off circuit 43 on the light receiving element side is electrically connected to the ground line FG whose function is grounded.

The digitra 45 has the same configuration as the photo relay 34 of the self-diagnosis circuit 3. The digitra 45 is electrically connected between the cathode of the light emitting element of the insulation monitoring on/off circuit 43 and one end of the detection shunt resistor 44b. A control end of the digitra 45 is electrically connected to a signal line (for example, GPIO) to which a control signal is supplied from the control circuit 215 of the in-vehicle charger 21.

The digitra 45 operates the insulation monitoring on/off circuit 43 under control of the control circuit 215 of the in-vehicle charger 21. In the digitra 45, an input resistor (not illustrated) connected to a base of a bipolar transistor (not illustrated) generates current in accordance with a voltage level of a GPIO line, and generates a collector current in accordance with a magnitude of the generated current. Then, in the insulation monitoring on/off circuit 43, a switch (not illustrated) on the light receiving element side is turned on by the collector current of the digitra 45 flowing through the light emitting element, and the power supply line connected via the limiting resistors 41a to 41d and the detection shunt resistor 44b are electrically connected. Thus, when the insulation monitoring on/off circuit 43 is turned on by the control circuit 215 of the in-vehicle charger 21, the power supply lines L1 to L3 and N are electrically connected to the detection shunt resistor 44b via the limiting resistors 41a to 41d and the high withstand voltage diode 42.

The detection shunt resistor 44b is electrically connected between one end of the switch on the light receiving element side of the digitra 45 opposite to the high withstand voltage diode 42 and the ground line FG functionally grounded.

One end of the Y capacitor 46 is electrically connected to one end of the detection shunt resistor 44b on the insulation monitoring on/off circuit 43 side via a resistor 44c. The other end of the Y capacitor 46 is electrically connected to the ground line FG functionally grounded. Thus, the Y capacitor 46 is electrically connected in parallel to the detection shunt resistor 44b. The RC circuit including the resistor 44c and the Y capacitor 46 adjusts the detection time related to the determination of dielectric breakdown by the insulation determination comparator 47.

One of the pair of input ends of the insulation determination comparator 47 is electrically connected to one end of the detection shunt resistor 44b on the insulation monitoring on/off circuit 43 side via the resistor 44c. The other of the pair of input ends of the insulation determination comparator 47 is electrically connected between the series resistors 44d and 44e. The resistors 44d and 44e are electrically connected between the insulated power supply 22 and the ground line FG functionally grounded, and generate a reference potential at the connection portion. Thus, the insulation determination comparator 47 detects the ground fault current flowing through the detection shunt resistor 44b by comparing the potential generated by the detection shunt resistor 44b with the reference potential generated by the resistors 44d and 44e. One of the pair of power supply terminals of the insulation determination comparator 47 is electrically connected to the insulated power supply 22, and the other is electrically connected to the ground line FG functionally grounded.

The output (voltage level at the output end) of the insulation determination comparator 47 is based on the value of the current flowing through the detection shunt resistor 44b. In one example, the voltage level at the output terminal of insulation determination comparator 47 changes to “H (high level)” when the dielectric breakdown of the Y capacitor (not illustrated) provided at the subsequent stage of the ground fault detection circuit 4 causes the ground fault current to flow to the detection shunt resistor 44b.

The digitra 48 has a configuration similar to that of the digitra 45. The digitra 48 is electrically connected between a cathode of a light emitting element (not illustrated) of the photocoupler and the ground line FG functionally grounded. A control end of the digitra 45 is electrically connected to an output end of the insulation determination comparator 47.

One end of the photocoupler 49 on the light emitting element side is electrically connected to the insulated power supply 22 via a resistor 44f. The other end on the light emitting element side of the photocoupler 49 is electrically connected to the output end of the digitra 45. One of a pair of terminals on the light receiving element side of the photocoupler 49 is electrically connected to a signal line (for example, GPIO) to which a control signal is supplied from the control circuit 215 of the in-vehicle charger 21, and the other is electrically connected to, for example, another ground line insulated from the ground line FG.

The digitra 48 operates the photocoupler 49 in accordance with the output of the insulation determination comparator 47. In the digitra 48, an input resistor (not illustrated) connected to a base of a bipolar transistor (not illustrated) generates current in accordance with a voltage level of an output end of the insulation determination comparator 47, and generates a collector current in accordance with a magnitude of the generated current. Then, in the photocoupler 49, a switch (not illustrated) on the light receiving element side is turned on by the collector current of the digitra 48 flowing through the light emitting element, and the voltage level of the GPIO line is changed. As a result, when detecting the ground fault current flowing through the detection shunt resistor 44b, the ground fault detection circuit 4 can notify the control circuit 215 of the in-vehicle charger 21.

The control circuit 215 of the in-vehicle charger 21 controls operations of the self-diagnosis circuit 3 and the ground fault detection circuit 4. The control circuit 215 is configured to determine feasibility relating to detection of a ground fault current by the insulation monitoring circuit 211 based on an operating state of each of the self-diagnosis circuit 3 and the ground fault detection circuit 4 and a detection result of the ground fault current by the ground fault detection circuit 4.

Specifically, in a case where the self-diagnosis circuit 3 is not operated, the control circuit 215 can detect the dielectric breakdown, namely, the occurrence of the ground fault (electric leakage), of the Y capacitor (not illustrated) provided at the subsequent stage of the ground fault detection circuit 4 based on the notification of the ground fault current detection from the ground fault detection circuit 4 in a state where the insulation monitoring on/off circuit 43 of the ground fault detection circuit 4 is turned on.

Additionally, in a case where the self-diagnosis circuit 3 is operated to perform the self-diagnosis, the control circuit 215 can detect the normal operation of the ground fault detection circuit 4 based on the notification of the ground fault current detection from the ground fault detection circuit 4 in the state where the insulation monitoring on/off circuit 43 of the ground fault detection circuit 4 is turned off.

Alternatively, in the above-mentioned case where when the self-diagnosis circuit 3 is operated to perform the self-diagnosis, the control circuit 215 can detect the malfunction of the ground fault detection circuit 4 based on the absence of the notification of the ground fault current detection from the ground fault detection circuit 4 in the state where the insulation monitoring on/off circuit 43 of the ground fault detection circuit 4 is turned off.

Note that the self-diagnosis executed by operating the self-diagnosis circuit 3 is responsible for the second safety of the in-vehicle charger 21 that verifies the feasibility of the ground fault detection circuit 4. This self-diagnosis may be performed at any timing during discharge, at which a ground fault current can flow when a short circuit is generated by functional grounding, may be performed at the start of discharge or at the end of discharge, or may be performed constantly or intermittently during discharge.

Note that the control circuit 215 includes one or more processors (not illustrated) and one or more memories (not illustrated), and may have a hardware configuration using a normal computer. As the control circuit 215, for example, a digital signal processor (DSP) can be used. Note that the control circuit 215 may implement each function of the control circuit 215 by a processor loading a program stored in a read only memory (ROM) or the like into a random access memory (RAM) and executing the loaded program, or may implement some or all of the functions with a dedicated hardware circuit (semiconductor integrated circuit or the like).

Note that the control circuit 215 that controls the operation of the self-diagnosis circuit 3 and the control circuit 215 that controls the operation of the ground fault detection circuit 4 described above may be implemented by the same circuit or may be implemented by different circuits independent from each other.

Note that the control circuit 215 may be implemented by an electronic control unit (ECU) provided inside the vehicle 2, a domain control unit (DCU) such as a cockpit domain controller (CDC) in which ECUs are integrated, or a computer such as an on board unit (OBU). Moreover, the control circuit 215 may transmit and receive information to and from another ECU provided in the vehicle via an in-vehicle network including a controller area network (CAN), Ethernet (registered trademark), a universal serial bus (USB) (registered trademark), or the like in the vehicle, or to and from an external power supply (power supply 9) connected to the vehicle, or may communicate with an information processing device outside the vehicle via a network such as the Internet.

As illustrated in FIGS. 1 and 2, the in-vehicle charger 21 includes a switch circuit 212.

The switch circuit 212 is electrically connected between the insulation monitoring circuit 211 and the power factor correction circuit 213 via the power supply lines L1 to L3 and N. The switch circuit 212 is electrically connected between the discharge terminals PO1 and PON of the in-vehicle charger 21 and the power factor correction circuit 213 via the power supply lines LO1 and LON. Thus, the power supply line LO1 is a voltage line branched from any of the power supply lines L1 to L3. The power supply line LON is a neutral line branched from the power supply line N.

Each of the power supply lines L1 to L3 and N according to the embodiment is an example of a first power supply line. Each of the power supply lines LO1 and LON according to the embodiment is an example of a second power supply line. The power supply line LO1 according to the embodiment is an example of a branch voltage line. The power supply line LON according to the embodiment is an example of a branch neutral line. In the case of the three-phase three-wire system, the power supply line N according to the embodiment is an example of a first power supply line and a second power supply line.

The discharging terminals PO1 and PON of the in-vehicle charger 21 are terminals electrically connected to the In-vehicle socket 29b (power source socket for discharging) of the vehicle 2. The power supply lines LO1 and LON are connected to the discharge terminals PO1 and PON, respectively. In one example, the power supply line LO1 is a voltage line through which a single-phase current from the power factor correction circuit 213 based on a direct current from the battery 23 flows. In one example, the power supply line LON is a neutral line electrically connected to each of the power supply line N and the ground potential.

The switch circuit 212 operates under the control of the control circuit 215 of the in-vehicle charger 21. For example, the switch circuit 212 electrically connects the insulation monitoring circuit 211 and the power factor correction circuit 213 via the power supply lines L1 to L3 and N at the time of charging and discharging the vehicle 2 via the AC socket 29a. At the time of discharging from the vehicle 2 via the in-vehicle socket 29b, the switch circuit 212 electrically connects the discharging terminals PO1 and PON of the in-vehicle charger 21 and the power factor correction circuit 213 via the power supply lines LO1 and LON.

As described above, in the insulation monitoring circuit 211 (electric leakage detection circuit) according to the present disclosure, the self-diagnosis circuit 3 includes the relay circuit 31 that switches, among the power supply lines L1 to L3 and N, a power supply line to be connected to the limiting resistor 33 and thereby given the short-circuit path.

In the limiting resistor 33, the number of the high withstand voltage resistance elements connected in series is needed to increase as the withstand voltage requirement required for the self-diagnosis circuit 3 such as lightning surge increases. Under such circumstances, in the self-diagnosis circuit 3 according to the present disclosure, the limiting resistor 33 is shared among the power supply lines for which a ground fault is detected by the ground fault detection circuit 4 by providing the relay circuit 31. Thus, in the self-diagnosis circuit 3 according to the present disclosure, the limiting resistor 33 does not need to be provided in each of the power supply lines.

Therefore, with the insulation monitoring circuit 211 according to the present disclosure, it is possible to suppress the number of high withstand voltage resistance elements that increases as the withstand voltage request to the self-diagnosis circuit 3 increases. In one example, with the three-phase four-wire configuration illustrated in FIG. 2, the circuit configuration between the relay circuit 31 and the ground line FG can be shared and reduced by ¼ times. In one example, the relay circuit 31 according to the present disclosure may be applied to a three-phase three-wire type configuration, and in this case, the circuit configuration between the relay circuit 31 and the ground line FG can be shared and reduced by ⅓ times. In one example, the relay circuit 31 according to the present disclosure may be applied to a single-phase two-wire type, and in this case, the circuit configuration between the relay circuit 31 and the ground line FG can be shared and reduced by ½ times.

In addition, the circuit scale and cost increase by the amount of the relay circuit 31 provided instead of the common circuit configuration between the relay circuit 31 and the ground line FG. However, the relay circuit 31 according to the present disclosure can be configured by, for example, a general-purpose relay circuit. In addition, since the short-circuit current of the relay circuit 31 is about several mA, an increase in size and cost can be suppressed. Thus, the circuit scale and the cost of the relay circuit 31 to be added are smaller than the circuit scale and the cost of the photo relay 34 to be shared and reduced.

As described above, according to the configuration in which the limiting resistor 33 is shared by providing the relay circuit 31, regarding the self-diagnosis circuit 3 provided in the insulation monitoring circuit 211, an increase in the number of components and the circuit scale can be suppressed, and the cost can be reduced. In addition, since the circuit scale of the self-diagnosis circuit 3 is suppressed, the size of the circuit board on which they are mounted and the volume occupied by the circuit board on which they are mounted are also suppressed, and the size of the insulation monitoring circuit 211 and the in-vehicle charger 21 can be reduced.

Moreover, since the circuit configuration at the subsequent stage of the limiting resistor 33 is also shared, the number of signal lines (for example, GPIO lines) connecting the control circuit 215 such as a microcomputer and the self-diagnosis circuit 3 can be reduced. This advantage can facilitate the routing of the wiring, so that it is possible to improve the degree of freedom of component arrangement in the in-vehicle charger 21. Additionally, it is also possible to increase the number of empty ports of the control circuit 215, and/or implement the control circuit 215 by an inexpensive microcomputer with few GPIO terminals.

Note that the power supply lines LO1 and LON through which the current supplied to the discharge terminals PO1 and PON connected to the in-vehicle socket 29b provided in, for example, the vehicle interior of the vehicle 2 flows may be included in the target of the electric leakage detection by the ground fault detection circuit 4. In this case, in the ground fault detection circuit 4, limiting resistors having the same configuration are electrically connected between each of the power supply lines LO1 and LON and the high withstand voltage diode 42, in parallel with the limiting resistors 41a to 41d of the power supply lines L1 to L3 and N. Additionally, in the self-diagnosis circuit 3, the relay circuit 31 switches the phase to which the limiting resistor 33 is connected, among multiple phases corresponding to the power supply lines including the power supply lines LO1 and LON in addition to the power supply lines L1 to L3 and N. Even with this configuration, the same effects as those of the above-described embodiment can be obtained. Furthermore, by providing the relay circuit 31, it is possible to further enhance an effect of suppressing an increase in circuit scale in the self-diagnosis circuit 3 when the limiting resistor 33 is made common.

Note that the power supply lines N and LON are branched in the switch circuit 212 as illustrated in FIG. 2, but the present invention is not limited thereto. In one example, the power supply lines N and LON may be branched on the power supply 9 side from the connection position of the relay circuit 31 to the power supply line N. According to this configuration, when the power supply lines LO1 and LON through which the current supplied to the discharge terminals PO1 and PON flows are included in the target of the electric leakage detection by the ground fault detection circuit 4, the self-diagnosis of the power supply lines N and LON can be collectively performed. Therefore, according to this configuration, it is possible to suppress an increase in the circuit scale in the self-diagnosis circuit 3 due to the provision of the relay circuit 31.

According to at least one embodiment described above, regarding the self-diagnosis circuit provided in the electric leakage detection circuit, it is possible to suppress an increase in circuit scale.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Appendix

The following technique is disclosed by the above-described embodiments.
(1)

An electric leakage detection circuit comprising:
a ground fault detection circuit electrically connected to power supply lines to which AC power is supplied, the ground fault detection circuit being configured to detect a ground fault current with respect to a ground potential of each of the power supply lines; and
a self-diagnosis circuit configured to generate a short-circuit path by which each of the power supply lines is selectively short-circuited to a connection line of the ground potential, the self-diagnosis circuit including
   a first limiting resistor including a plurality of resistance elements electrically connected in series, one end of the first limiting resistor being electrically connected to the connection line of the ground potential, and
   a relay circuit provided between the power supply lines and a side opposite to the connection line of the ground potential of the first limiting resistor, the relay circuit being configured to switch, among the power supply lines, a power supply line to be electrically connected to the first limiting resistor and given the short-circuit path.
(2)

The electric leakage detection circuit according to the above-described (1), wherein the self-diagnosis circuit further includes a photo-relay electrically connected between the first limiting resistor and the connection line of the ground potential.
(3)

The electric leakage detection circuit according to the above-described (1) or (2), wherein the ground fault detection circuit includes:
second limiting resistors electrically connected to the power supply lines, each of the second limiting resistors including a plurality of resistance elements electrically connected in series;
a diode whose anode is electrically connected to each of the second limiting resistors on a side opposite to the power supply lines and whose cathode is electrically connected to a connection line of the ground potential via a detection shunt resistor serving to detect the ground fault current; and
an insulation determination comparator configured to detect the ground fault current flowing through the detection shunt resistor by comparing a potential generated by the detection shunt resistor with a reference potential.
(4)

The electric leakage detection circuit according to any one of the above-described (1) to (3), wherein
the AC power has three-phases, and
the power supply lines are four lines including three voltage lines and one neutral line, and
the relay circuit includes three C contact relays configured to electrically connect the first limiting resistor to one of the four power supply lines.
(5)

The electric leakage detection circuit according to any one of the above-described (1) to (4), wherein the power supply lines include:
four first power supply lines including three voltage lines and one neutral line, and the four first power supply lines being supplied with the AC power during charging and discharging; and
one or more second power supply lines including a branch voltage line branched from one of the three voltage lines of the first power supply line, the second power supply lines being supplied with the AC power during discharge.
(6)

The electric leakage detection circuit according to the above-described (5), wherein the second power supply lines include a branch neutral line branched from the neutral line of the first power supply line.
(7)

The electric leakage detection circuit according to any one of the above-described (1) to (3), wherein
the AC power has a single-phase, and
the power supply lines are two lines including one voltage line and one neutral line, and
the relay circuit includes one C contact relay configured to electrically connect the first limiting resistor to one of the two power supply lines.
(8)

The electric leakage detection circuit according to any one of the above-described (2) to (7), wherein the photo relay of the self-diagnosis circuit is turned on every time the relay circuit changes a power supply line to which the first limiting resistor is to be connected.
(9)

A power conversion device including:
an electric leakage detection circuit according to any one of the above-described (1) to (8); and
a control circuit configured to
   control operations of the ground fault detection circuit and the self-diagnosis circuit, and
   determine feasibility of detection of the ground fault current based on respective operating states of the ground fault detection circuit and the self-diagnosis circuit and a detection result of the ground fault current by the ground fault detection circuit.
(10)

The power conversion device including:
the electric leakage detection circuit according to any one of the above-described (1) to (8); and
a power conversion circuit electrically connected to the electric leakage detection circuit via the power supply lines, the power conversion circuit being configured to convert the AC power from an external AC power supply into DC power.
(11)

A vehicle including:
the power conversion device according to the above-described (9) or (10), which is configured to convert the AC power from an external AC power supply into DC power; and
a battery charged using the DC power.
(12)

The vehicle according to the above-described (11), wherein the power conversion device is configured to convert DC power from the battery into the AC power and supply the AC power to an external load connected to the vehicle.

What is claimed is:

1. An electric leakage detection circuit comprising:
a ground fault detection circuit electrically connected to power supply lines to which AC power is supplied, the ground fault detection circuit being configured to detect a ground fault current with respect to a ground potential of each of the power supply lines; and
a self-diagnosis circuit configured to generate a short-circuit path by which each of the power supply lines is selectively short-circuited to a connection line of the ground potential, the self-diagnosis circuit including
a first limiting resistor including a plurality of resistance elements electrically connected in series, one end of the first limiting resistor being electrically connected to the connection line of the ground potential, and
a relay circuit provided between the power supply lines and a side opposite to the connection line of the ground potential of the first limiting resistor, the relay circuit being configured to switch, among the power supply lines, a power supply line to be electrically connected to the first limiting resistor and given the short-circuit path.

2. The electric leakage detection circuit according to claim 1, wherein the self-diagnosis circuit further includes a photo-relay electrically connected between the first limiting resistor and the connection line of the ground potential.

3. The electric leakage detection circuit according to claim 1, wherein the ground fault detection circuit includes:
second limiting resistors electrically connected to the power supply lines, each of the second limiting resistors including a plurality of resistance elements electrically connected in series;
a diode whose anode is electrically connected to each of the second limiting resistors on a side opposite to the power supply lines and whose cathode is electrically connected to a connection line of the ground potential via a detection shunt resistor serving to detect the ground fault current; and
an insulation determination comparator configured to detect the ground fault current flowing through the detection shunt resistor by comparing a potential generated by the detection shunt resistor with a reference potential.

4. The electric leakage detection circuit according to claim 1, wherein
the AC power has three-phases, and
the power supply lines are four lines including three voltage lines and one neutral line, and
the relay circuit includes three C contact relays configured to electrically connect the first limiting resistor to one of the four power supply lines.

5. The electric leakage detection circuit according to claim 1, wherein the power supply lines include:
four first power supply lines including three voltage lines and one neutral line, and the four first power supply lines being supplied with the AC power during charging and discharging; and
one or more second power supply lines including a branch voltage line branched from one of the three voltage lines of the first power supply line, the second power supply lines being supplied with the AC power during discharge.

6. The electric leakage detection circuit according to claim 5, wherein the second power supply lines include a branch neutral line branched from the neutral line of the first power supply line.

7. The electric leakage detection circuit according to claim 1, wherein
the AC power has a single-phase, and
the power supply lines are two lines including one voltage line and one neutral line, and
the relay circuit includes one C contact relay configured to electrically connect the first limiting resistor to one of the two power supply lines.

8. The electric leakage detection circuit according to claim 2, wherein the photo relay of the self-diagnosis circuit is turned on every time the relay circuit changes a power supply line to which the first limiting resistor is to be connected.
